(19) United States
(12) Patent Application Publication
(10) Pub. No.: US 2026/0305406 A1
(43) Pub. Date: Oct. 1, 2026

(54) ARCHITECTURE FOR DIE-SIDE COMPONENT ATTACHED PACKAGES

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 19/091,499

(22) Filed: Mar. 26, 2025

(51) Int. Cl. H01L 23/538; H01L 21/48; H01L 25/18; H10D 1/68

(52) U.S. Cl. CPC H10W 70/65; H10W 70/093; H10W 70/611; H10W 90/00; H10D 1/68

(57) ABSTRACT

Disclosed are architectures for die-side component attached packages. In an aspect, a semiconductor package apparatus includes a substrate having a first surface and a second surface opposite the first surface and having a first metal layer, disposed on the first surface of the substrate, that provides electrical traces for electrically coupling to a semiconductor die to be mounted to the substrate. A riser structure is disposed above a sub-portion of the first surface of the substrate that includes at least some of the electrical traces. The riser structure includes an insulating structure having a third surface in contact with the first surface of the substrate and a fourth surface opposite the third surface, and a second metal layer, disposed on the fourth surface of the insulating structure, that provides additional electrical traces for electrically coupling a component to be mounted to the riser structure to the substrate.

### BACKGROUND OF THE DISCLOSURE

### 1. Field of the Disclosure

Aspects of the disclosure relate generally to semiconductor device packages, and more particularly to packages having die-side components.

### 2. Description of the Related Art

Some conventional device packages comprise a multi-layer laminate substrate onto which a processor die or other chiplet is attached in a “flip-chip” configuration, i.e., with the contact pads of the processor die facing toward the substrate and contacting corresponding contact structures on the surface of the substrate. The surface of the substrate facing the processor die is referred to as the “die side” of the substrate and the opposite surface of the substrate from the processor die, is referred to as the “line side” of the substrate.

Other electrical components may also be mounted to the die side of the substrate, and thus may be generically referred to as “die-side components” (DSCs). Capacitors are a common die-side component, and thus the acronym DSC may refer specifically to a die side capacitor. Capacitors are commonly used to filter power supply signals or provide noise isolation for chiplets, and it is desirable to locate such capacitors as close as possible to the chiplet.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an apparatus includes a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and a riser structure disposed above a portion of the first surface of the substrate, the portion occupying an area that is less than a total area of the first surface of the substrate, the portion including at least some of the first plurality of electrical traces, the riser structure comprising: a first insulating structure having a third surface in contact with the first surface of the substrate and a fourth surface opposite the third surface; and a second metal layer disposed on the fourth surface of the first insulating structure, the second metal layer comprising a second plurality of electrical traces for electrically coupling to a component to be mounted to the riser structure.

In an aspect, an apparatus includes a substrate comprising a first surface and a second surface opposite the first surface, the substrate further comprising a first metal layer disposed on the first surface of the substrate, the first metal layer comprising a first plurality of electrical traces, and a second metal layer disposed on the second surface of the substrate, the second metal layer comprising a second plurality of electrical traces; a first riser structure disposed above a portion of the first surface of the substrate, the portion occupying an area that is less than a total area of the first surface of the substrate, the portion including at least some of the first plurality of electrical traces, the first riser structure comprising a first insulating structure having a third surface in contact with the first surface of the substrate and a fourth surface opposite the third surface, and a third metal layer disposed on the fourth surface of the first insulating structure, the third metal layer comprising a third plurality of electrical traces for electrically coupling the substrate to a component to be mounted to the first riser structure; and a second riser structure disposed above a portion of the second surface of the substrate, the portion occupying an area that is less than a total area of the second surface of the substrate, the portion including at least some of the second plurality of electrical traces, the second riser structure comprising a second insulating structure having a fifth surface in contact with the second surface of the substrate and a sixth surface opposite the fifth surface, and a fourth metal layer disposed on the sixth surface of the second insulating structure, the fourth metal layer comprising a fourth plurality of electrical traces for electrically coupling the substrate to a component to be mounted to the second riser structure.

In an aspect, a method of fabricating an apparatus includes providing a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and forming a riser structure disposed above a portion of the first surface of the substrate, the portion occupying an area that is less than a total area of the first surface of the substrate, the portion including at least some of the first plurality of electrical traces, wherein forming the riser structure comprises forming a first insulating structure having a third surface in contact with the first surface of the substrate and a fourth surface opposite the third surface; and forming a second metal layer disposed on the fourth surface of the first insulating structure, the second metal layer comprising a second plurality of electrical traces for electrically coupling to a component to be mounted to the riser structure.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof. The relative terms “top”, “bottom”, “upper”, “lower”, etc., are terms of convenience and are not intended to be limiting. Directional terms such as upper, lower, above, and below are used herein for ease of description and often refer to illustrations in the application figures. Such terms are not necessarily descriptive of a physical direction or disposition or positioning of a device.

FIG. 1 is a cross-sectional view of a conventional package with a die-side component (DSC).

FIGS. 2A-2B are plan views illustrating conventional techniques for accommodating a DSC.

FIG. 3 is a cross-sectional view of a package with a riser structure and DSC, according to aspects of the disclosure.

FIGS. 4A-4B are plan views illustrating an example riser structure and DSC, according to aspects of the disclosure.

FIG. 5 is a plan view of an example package with multiple riser structures and DSCs, according to aspects of the disclosure.

FIG. 6 is a flow chart illustrating a portion of a simplified process for producing substrates with riser structures, according to an aspect of the disclosure.

FIG. 7 is a flowchart of an example method for producing substrates with riser structures, according to an aspect of the disclosure.

FIG. 8 illustrates a mobile device, according to aspects of the disclosure.

FIG. 9 illustrates various electronic devices that may be integrated with any of the devices disclosed herein.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Various aspects relate generally to semiconductor device packages. Some aspects more specifically relate to packages having die-side components. In an aspect, a semiconductor package apparatus includes a substrate having a first surface and a second surface opposite the first surface and having a first metal layer, disposed on the first surface of the substrate, that provides electrical traces for electrically coupling to a semiconductor die to be mounted to the substrate. A riser structure is disposed above a sub-portion of the first surface of the substrate that includes at least some of the electrical traces. The riser structure includes an insulating structure having a third surface in contact with the first surface of the substrate and a fourth surface opposite the third surface, and a second metal layer, disposed on the fourth surface of the insulating structure, that provides additional electrical traces for electrically coupling a component to be mounted to the riser structure to the substrate.

Particular aspects of the subject matter described in this disclosure can be implemented to realize one or more of the following potential advantages. In some examples, the use of riser structures for die-side components (DSCs) provide additional areas for routing signals in the top metal layer of a multi-layer substrate. This can simplify breakout planning of die peripheral bumps, provide better skew matching for high-speed interfaces, and allows DSCs to be placed closer to a die also mounted to the die side of the substrate, which in some cases can improve the performance of power distribution networks (PDNs).

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

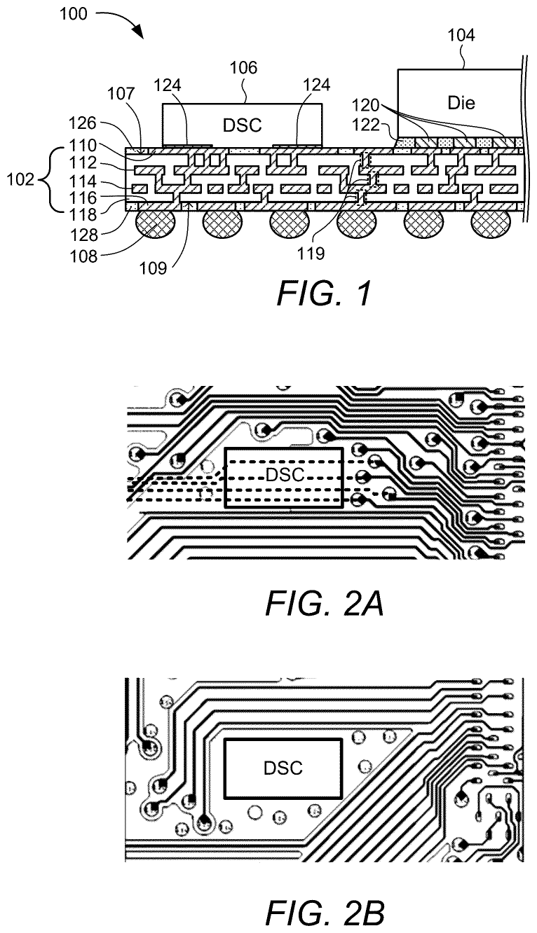

FIG. 1 is a cross-sectional view of a conventional package 100. In the example shown in FIG. 1, the package 100 comprises a multi-layer substrate 102; a processor die 104 and a die-side component (DSC) 106 (e.g., a capacitor) are mounted to a first surface 107 of the substrate 102, referred to herein as the “die side” of the substrate 102, and a ball grid array (BGA) or other type of contacts 108 are mounted to a second surface 109 of the substrate opposite the first surface 107 of the substrate, referred to herein as the “line side” of the substrate. In the example shown in FIG. 1, the substrate 102 includes a first metal (M1) layer 110, a second metal (M2) layer 112, a third metal (M3) layer 114, and a fourth metal (M4) layer 116, separated from each other by a substrate dielectric 118. As shown in FIG. 1, vertical vias 119 provide electrical connections between metal layers.

For simplicity of discussion, the metal layer closest to the die side of the substrate may be referred to herein as the “top”, “top-most”, or “uppermost” metal layer, and the metal layer closest to the line side of the substrate may be referred to as the “bottom”, “bottom-most”, or “lowermost” metal layer. When used in reference to the substrate 102 shown in FIG. 1, the M1 layer 110 is the “top” layer and the M4 layer 116 is the “bottom” layer. Thus, in the example shown in FIG. 1, the M1 layer 110 sits on and extends above the first surface 107 of the substrate 102, but may alternatively be slightly or fully embedded within the substrate 102 such that the top surface of the M1 layer 110 is flush with the first surface 107. Likewise, in the example shown in FIG. 1, the M4 layer 116 sits on and extends below the second surface 109 of the substrate 102, but may alternatively be slightly or fully embedded within the substrate 102 such that the bottom surface of the M4 layer 116 is flush with the second surface 109. The relative terms “top”, “bottom”, “upper”, “lower”, etc., are terms of convenience and are not intended to be limiting.

The processor die 104 includes a set of contact structures 120 that are electrically connected to corresponding M1 layer 110 contact structures, and encapsulated within an insulating material 122. The DSC 106 includes a set of contact structures 124 that are electrically connected to corresponding M1 layer 110 contact structures. In the example shown in FIG. 1, the cross-sectional view also shows the presence of a die-side solder mask layer 126 and a line-side solder mask layer 128. It is noted that a solder mask layer may alternatively be referred to herein as a solder resist (SR) layer. A typical processor die 104 has a vertical thickness greater than 300 microns, while a typical DSC 106 has a vertical thickness in the 100-150 micron range. Where the substrate 102 is comprised of layers of pre-preg, each layer is typically 10-30 microns thick; a four-layer pre-preg substrate, for example, typically ranges in thickness from 40-120 microns.

Premium tier (PT) packages are layer count limited, however, and increasing input/output (I/O) counts require increasing numbers of I/O power traces and a corresponding increase in capacitor counts (e.g., 20 or more capacitors, depending on the size of the die and the requirements of the power distribution network (PDN)). Current package-on-package (POP) solutions tend to use line-side capacitors because the M1 layer is already routing limited-generally, the die attach layer (i.e., M1), includes all signal breakouts around the package edges- and the addition of a DSC would reduce the already-crowded M1 routing area, since each DSC would be surrounded by a routing keepout region. Adding more die-side capacitors could increasing the area of the package and/or require additional routing layers within the substrate. The keepout regions surrounding each DSC also causes routing challenges and can negatively affect signal integrity and timing.

FIGS. 2A-2B are plan views illustrating conventional techniques for accommodating a DSC. Since the DSC electrically contacts the upper-most die-side metal layer (e.g., the M1 layer), other signals cannot be routed through the region of the die side of the substrate that is occupied by the DSC. FIG. 2A shows a first approach, which is to route the other signals down to a lower metal layer (e.g., the M2 layer) and under the DSC. FIG. 2B shows a second approach, which is to leave the other signals in the upper-most die side metal layer but route them around the perimeter of the DSC, i.e., so that they stay outside of the keep-out region surrounding the DSC. Each approach has disadvantages: the first approach may cause routing congestion within the multiple layers of the substrate, or may necessitate the substrate to have additional metal routing layers to accommodate routing the signals underneath the DSC, and the second approach may cause routing congestion within the uppermost die-side metal layer or may necessitate an increase in the size of the substrate to provide the needed area for routing the signals around the DSC.

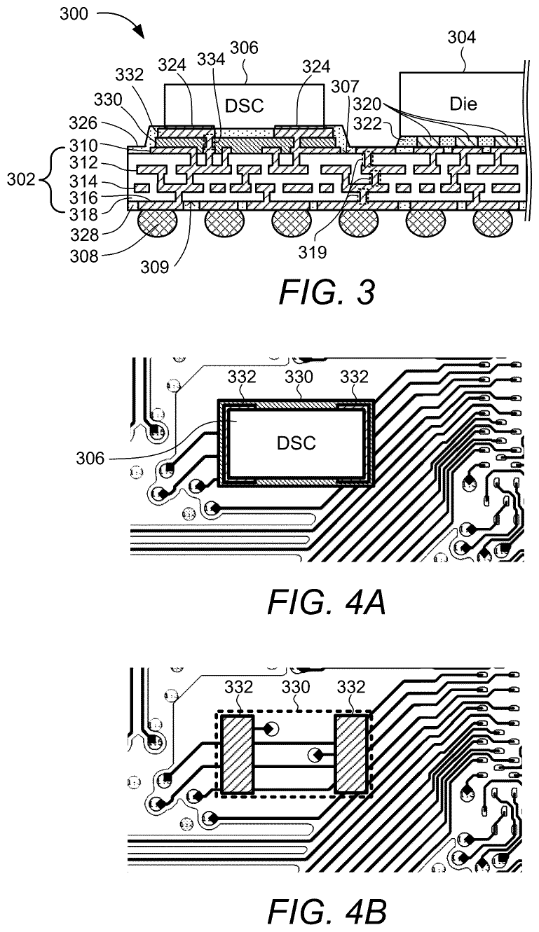

FIG. 3 is a cross-sectional view of a package 300 with a riser structure and DSC, according to aspects of the disclosure. In the example shown in FIG. 3, the package 300 comprises a multi-layer substrate 302. A processor die 304 is mounted directly to a first surface 307 of the substrate, referred to herein as the “die side” of the substrate 302, and a die-side component (DSC) 306 is mounted to a riser structure located on the first surface 307 of the substrate 302, which will be described in more detail below. A ball grid array (BGA) or other type of contacts 308 are mounted to a second surface 309 of the substrate opposite the first surface 307 of the substrate, referred to herein as the line side of the substrate.

In the example shown in FIG. 3, the substrate 302 includes a first metal (M1) layer 310, a second metal (M2) layer 312, a third metal (M3) layer 314, and a fourth metal (M4) layer 316, separated from each other by a substrate dielectric 318. As shown in FIG. 3, vertical vias 319 provide electrical connections between metal layers. The M1 layer 310 includes a set of electrical traces for electrically coupling to the processor die 304 and other die-side components. For simplicity of discussion, the metal layer closest to the die side of the substrate may be referred to herein as the “top”, “top-most”, or “uppermost” metal layer, and the metal layer closest to the line side of the substrate may be referred to as the “bottom”, “bottom-most”, or “lowermost” metal layer. When used in reference to the substrate 302 shown in FIG. 3, the M1 layer 310 is the “top” layer and the M4 layer 316 is the “bottom” layer. Thus, in the example shown in FIG. 3, the M1 layer 310 sits on and extends above the first surface 307 of the substrate 302, but may alternatively be slightly or fully embedded within the substrate 302 such that the top surface of the M1 layer 310 is flush with the first surface 307. Likewise, in the example shown in FIG. 3, the M4 layer 316 sits on and extends below the second surface 309 of the substrate 302, but may alternatively be slightly or fully embedded within the substrate 302 such that the bottom surface of the M4 layer 316 is flush with the second surface 309. The relative terms “top”, “bottom”, “upper”, “lower”, etc., are terms of convenience and are not intended to be limiting.

In the examples shown in FIG. 3, the processor die 304 includes a set of contact structures 320 that are electrically connected to corresponding M1 layer 310 contact structures, and encapsulated within an insulating material 322. The DSC 306 also includes a set of contact structures 324. In the example shown in FIG. 3, the cross-sectional view also shows the presence of a die-side SR layer 326 and a line-side SR layer 328. A typical processor die 304 has a vertical thickness greater than 300 microns, while a typical DSC 306 has a vertical thickness in the 100-150 micron range. Where the substrate 302 is comprised of layers of pre-preg, each layer is typically 10-30 microns thick; a four-layer pre-preg substrate, for example, typically ranges in thickness from 40-120 microns.

As shown in FIG. 3, the package 300 further includes a riser structure disposed above a portion of the die-side surface of the substrate, the portion occupying an area that is less than a total area of the die-side surface of the substrate, the portion including at least some of the first plurality of electrical traces. In the example shown in FIG. 3, the riser structure comprises a first insulating structure 330 having a bottom surface in contact with the die-side surface of the substrate and a top surface opposite the bottom surface. In some aspects, the first insulating structure 330 comprises one or more layers of an insulating material. In the example shown in FIG. 3, the riser structure also includes an additional metallization structure 332, disposed on the top surface of the first insulating structure 330, that provides electrical traces for electrically coupling to the contact structures 324 of the DSC 306. The metallization structure includes one or more vertical vias 334 through the first insulating structure 330 to electrically connect the electrical traces of the metallization structure 332 to the electrical traces on and/or within the substrate 302, thus coupling at least some of the contact structures 324 of the DSC 306 to the substrate, and in some cases through the substrate to the processor die 304. As shown in FIG. 3, the electrical traces of the metallization structure 332 are higher above the die-side of the substrate 302 than are the contract structures 320 of the processor die 304.

Example materials for the first insulating structure 330 include, but are not limited to, Ajimoto built-up film (ABF), glass, woven fabric (e.g., pre-preg), thin polyimide, other dielectric materials, or a combination thereof. In some aspects, the first insulating structure 330 and the substrate dielectric 318 are the same material as each other. In some aspects, the first insulating structure 330 and the substrate dielectric 318 may be different materials from each other.

FIG. 4A and FIG. 4B are plan views illustrating an example riser structure and DSC, according to aspects of the disclosure. As shown in FIGS. 4A-4B, the insulating structure 330 allows the DSC 306 to be located directly over routing signals in the upper-most die-side routing layer—meaning that a keep-out region is no longer needed for M1 signals. FIG. 4A shows example relative locations of the insulating structure 330, the electrical traces of the additional metallization structure 332, and the DSC 306. FIG. 4B illustrates the point that the riser structure obviates the need to route those signals around or under the DSC 306, which results in more area for M1 routing and may result in better signal integrity and less timing skew.

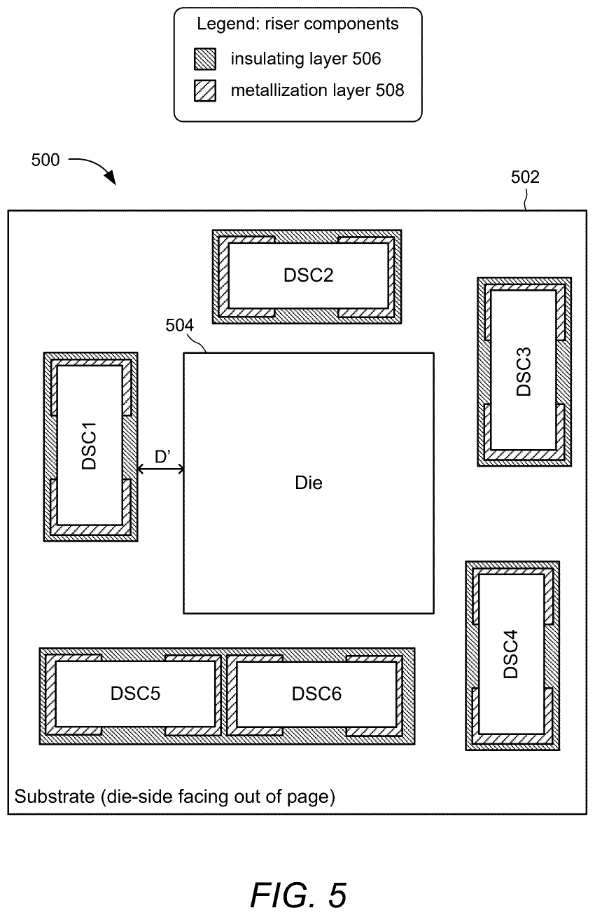

FIG. 5 is a plan view of an example package 500 with multiple riser structures and DSCs, according to aspects of the disclosure. In the example shown in FIG. 5, the example package 500 comprises a substrate 502, shown die-side up in FIG. 5, upon which is mounted a die 504 and a number of die-side components, labeled DSC1 through DSC6. Each die-side component is mounted on a DSC riser structure comprising an insulating layer 506 atop the die-side surface of the substrate 502, and a metallization layer 508 atop the insulating layer 506. The metallization layers 508 provide electrical connections between the routing layers of the substrate 502 and the die-side components. FIG. 5 illustrates an embodiment in which multiple DSCs (i.e., DSC5 and DSC6) share or occupy the same riser structure.

FIG. 5 illustrates the point that the minimum distance D′ between a die 504 and a DSC on a riser structure can be smaller than currently allowed for conventional package designs that don't use a riser structure. For example, where a conventional package requires D′ to be 500 microns, using a riser structure according to aspects of the disclosure requires D′ to be only 250 microns.

It will be understood that a riser structure may also or alternatively be located on the line-side of the substrate 502, i.e., where the insulating layer 506 is closest to the lowest metal layer of the substrate 502. This would allow a line side component to be placed over electrical traces in the lowest metal layer, and would obviate the need to reroute those electrical traces around the line side component in the lowest metal layer, or up and over the line side component (i.e., further into the substrate 502 from line side).

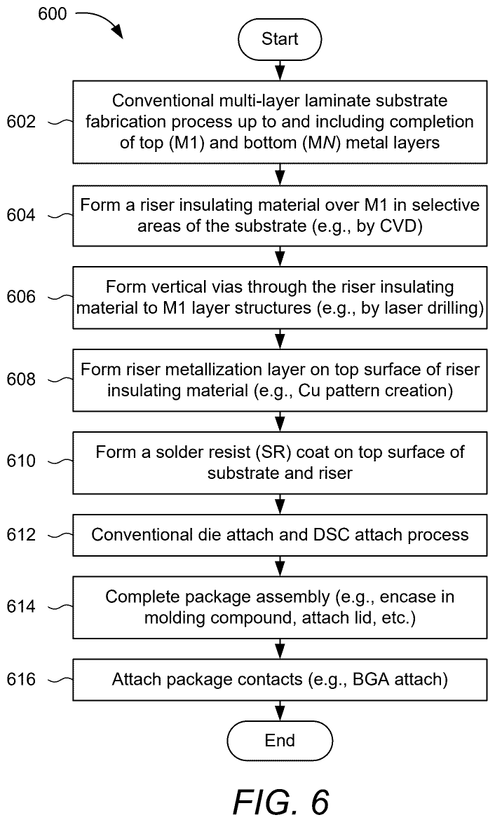

FIG. 6 is a flow chart illustrating a portion of a simplified process 600 for producing substrates with riser structures, according to an aspect of the disclosure.

The process 600 includes, at block 602, preparing a substrate using a multi-layer substrate fabrication process up to and including completion of top (M1) and bottom (MN) metal layers.

The process 600 further includes, at block 604, forming a riser insulating material over M1 in selective areas of the substrate. In some aspects, the riser insulating material may be formed using a chemical vapor deposition (CVD) process or other technique to from the riser insulating material.

The process 600 further includes, at block 606, forming vertical vias through the riser insulating material to M1 layer structures. In some aspects, these vertical vias may be formed by laser drilling through the riser insulating material.

The process 600 further includes, at block 608, forming a riser metallization structure on the top surface of the riser insulating material. In some aspects, this may be done using a copper (Cu) patterning process. The riser insulating material and riser metallization structure constitute the riser structure.

The process 600 further includes, at block 610, forming a solder resist (SR) coat on the top surface of the substrate and riser structure.

The process 600 further includes, at block 612, using a die attach process to mount the die to the substrate and using a DSC attach process to mount the DSC to the riser structure.

The process 600 further includes, at block 614, completing the package assembly process. In some aspects, this may include encasing the substrate, the die, the riser structure, and the DSC in a molding compound, attaching a lid to the package, etc., depending on the specific package type.

The process 600 further includes, at block 616, attaching package contacts to the bottom of the substrate. In some aspects, this includes performing a ball grid array (BGA) attach process.

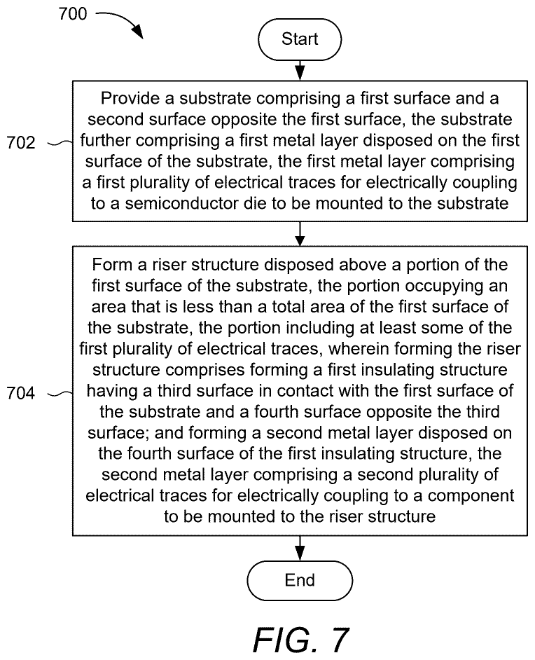

FIG. 7 is a flowchart of an example method 700 for producing substrates with riser structures, according to an aspect of the disclosure. As shown in FIG. 7, method 700 may include, at block 702, providing a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate.

As further shown in FIG. 7, method 700 may include, at block 704, forming a riser structure disposed above a portion of the first surface of the substrate, the portion occupying an area that is less than a total area of the first surface of the substrate, the portion including at least some of the first plurality of electrical traces, wherein forming the riser structure comprises forming a first insulating structure having a third surface in contact with the first surface of the substrate and a fourth surface opposite the third surface; and forming a second metal layer disposed on the fourth surface of the first insulating structure, the second metal layer comprising a second plurality of electrical traces for electrically coupling to a component to be mounted to the riser structure.

Method 700 may include additional implementations, such as any single implementation or any combination of implementations described below and/or in connection with one or more other methods described elsewhere herein. Although FIG. 7 shows example blocks of method 700, in some implementations, method 700 may include additional blocks, fewer blocks, different blocks, or differently arranged blocks than those depicted in FIG. 7. Additionally, or alternatively, two or more of the blocks of method 700 may be performed in parallel.

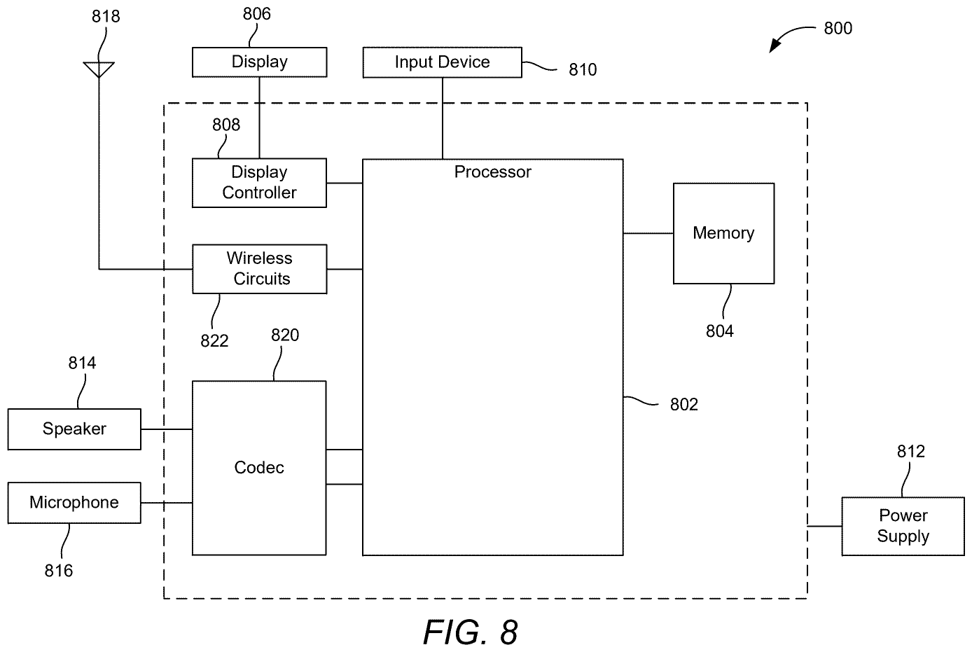

FIG. 8 illustrates a mobile device 800, according to aspects of the disclosure. In some aspects, the mobile device 800 may be implemented by including one or more IC devices manufactured based on the examples described in this disclosure. In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

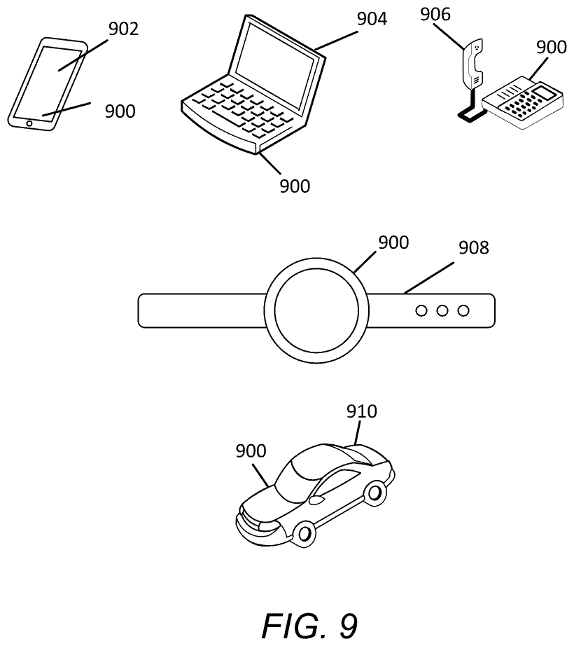

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., package 300) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:
Clause 1. An apparatus, comprising: a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and a riser structure disposed above a portion of the first surface of the substrate, the portion occupying an area that is less than a total area of the first surface of the substrate, the portion including at least some of the first plurality of electrical traces, the riser structure comprising: a first insulating structure having a third surface in contact with the first surface of the substrate and a fourth surface opposite the third surface; and a second metal layer disposed on the fourth surface of the first insulating structure, the second metal layer comprising a second plurality of electrical traces for electrically coupling to a component to be mounted to the riser structure.
Clause 2. The apparatus of clause 1, wherein at least one electrical trace of the second plurality of electrical traces is electrically coupled to at least one electrical trace of the first plurality of electrical traces.
Clause 3. The apparatus of any of clauses 1 to 2, wherein the substrate comprises a plurality of metal layers separated from each other by a substrate dielectric material and wherein the first metal layer is one of the plurality of metal layers.
Clause 4. The apparatus of clause 3, wherein the substrate dielectric material comprises at least one of Ajimoto built-up film (ABF), glass, pre-preg, polyimide, or a combination thereof.
Clause 5. The apparatus of any of clauses 3 to 4, wherein the substrate dielectric material has a vertical thickness in a range from 10 microns to 30 microns.
Clause 6. The apparatus of any of clauses 3 to 5, wherein at least one electrical trace of the second plurality of electrical traces is electrically coupled to at least one of the plurality of metal layers within the substrate.
Clause 7. The apparatus of any of clauses 1 to 6, wherein the first insulating structure comprises a layer of a dielectric material disposed on the first surface of the substrate.
Clause 8. The apparatus of clause 7, wherein the dielectric material comprises at least one of Ajimoto built-up film (ABF), glass, pre-preg, polyimide, or a combination thereof.
Clause 9. The apparatus of any of clauses 1 to 8, further comprising a semiconductor die mounted to the first surface of the substrate or the second surface of the substrate and being electrically coupled to the first plurality of electrical traces.
Clause 10. The apparatus of clause 9, wherein a vertical thickness of the semiconductor die is greater than 300 microns.
Clause 11. The apparatus of any of clauses 9 to 10, further comprising a component mounted to the riser structure and being electrically coupled to the second plurality of electrical traces.
Clause 12. The apparatus of clause 11, wherein the component comprises a capacitor.
Clause 13. The apparatus of any of clauses 11 to 12, wherein the a vertical thickness of the component is less than 300 microns.
Clause 14. The apparatus of any of clauses 11 to 13, wherein a vertical thickness of the component is in a range from 100 microns to 150 microns.
Clause 15. The apparatus of any of clauses 11 to 14, wherein a vertical thickness of the semiconductor die is greater than a combined vertical thickness of the riser structure and the component mounted to the riser structure.
Clause 16. The apparatus of any of clauses 11 to 15, wherein the semiconductor die is mounted to the first surface of the substrate.
Clause 17. The apparatus of clause 16, wherein a minimum horizontal spacing between the semiconductor die and the riser structure is 250 microns.
Clause 18. The apparatus of any of clauses 11 to 17, further comprising a plurality of contact structures disposed on the second surface of the substrate.
Clause 19. The apparatus of clause 18, wherein the plurality of contact structures comprise a ball grid array (BGA).
Clause 20. The apparatus of any of clauses 1 to 19, wherein the apparatus is incorporated into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 21. An apparatus, comprising: a substrate comprising a first surface and a second surface opposite the first surface, the substrate further comprising a first metal layer disposed on the first surface of the substrate, the first metal layer comprising a first plurality of electrical traces, and a second metal layer disposed on the second surface of the substrate, the second metal layer comprising a second plurality of electrical traces; a first riser structure disposed above a portion of the first surface of the substrate, the portion occupying an area that is less than a total area of the first surface of the substrate, the portion including at least some of the first plurality of electrical traces, the first riser structure comprising a first insulating structure having a third surface in contact with the first surface of the substrate and a fourth surface opposite the third surface, and a third metal layer disposed on the fourth surface of the first insulating structure, the third metal layer comprising a third plurality of electrical traces for electrically coupling the substrate to a component to be mounted to the first riser structure; and a second riser structure disposed above a portion of the second surface of the substrate, the portion occupying an area that is less than a total area of the second surface of the substrate, the portion including at least some of the second plurality of electrical traces, the second riser structure comprising a second insulating structure having a fifth surface in contact with the second surface of the substrate and a sixth surface opposite the fifth surface, and a fourth metal layer disposed on the sixth surface of the second insulating structure, the fourth metal layer comprising a fourth plurality of electrical traces for electrically coupling the substrate to a component to be mounted to the second riser structure.
Clause 22. A method of fabricating an apparatus, the method comprising: providing a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and forming a riser structure disposed above a portion of the first surface of the substrate, the portion occupying an area that is less than a total area of the first surface of the substrate, the portion including at least some of the first plurality of electrical traces, wherein forming the riser structure comprises forming a first insulating structure having a third surface in contact with the first surface of the substrate and a fourth surface opposite the third surface; and forming a second metal layer disposed on the fourth surface of the first insulating structure, the second metal layer comprising a second plurality of electrical traces for electrically coupling to a component to be mounted to the riser structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such. Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

What is claimed is:

1. An apparatus, comprising:
a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and
a riser structure disposed above a portion of the first surface of the substrate, the portion occupying an area that is less than a total area of the first surface of the substrate, the portion including at least some of the first plurality of electrical traces, the riser structure comprising:
a first insulating structure having a third surface in contact with the first surface of the substrate and a fourth surface opposite the third surface; and
a second metal layer disposed on the fourth surface of the first insulating structure, the second metal layer comprising a second plurality of electrical traces for electrically coupling to a component to be mounted to the riser structure.

2. The apparatus of claim 1, wherein at least one electrical trace of the second plurality of electrical traces is electrically coupled to at least one electrical trace of the first plurality of electrical traces.

3. The apparatus of claim 1, wherein the substrate comprises a plurality of metal layers separated from each other by a substrate dielectric material and wherein the first metal layer is one of the plurality of metal layers.

4. The apparatus of claim 3, wherein the substrate dielectric material comprises at least one of Ajimoto built-up film (ABF), glass, pre-preg, polyimide, or a combination thereof.

5. The apparatus of claim 3, wherein the substrate dielectric material has a vertical thickness in a range from 10 microns to 30 microns.

6. The apparatus of claim 3, wherein at least one electrical trace of the second plurality of electrical traces is electrically coupled to at least one of the plurality of metal layers within the substrate.

7. The apparatus of claim 1, wherein the first insulating structure comprises a layer of a dielectric material disposed on the first surface of the substrate.

8. The apparatus of claim 1, further comprising a semiconductor die mounted to the first surface of the substrate or the second surface of the substrate and being electrically coupled to the first plurality of electrical traces.

9. The apparatus of claim 8, wherein a vertical thickness of the semiconductor die is greater than 300 microns.

10. The apparatus of claim 8, further comprising a component mounted to the riser structure and being electrically coupled to the second plurality of electrical traces.

11. The apparatus of claim 10, wherein the component comprises a capacitor.

12. The apparatus of claim 10, wherein the a vertical thickness of the component is less than 300 microns.

13. The apparatus of claim 10, wherein a vertical thickness of the component is in a range from 100 microns to 150 microns.

14. The apparatus of claim 10, wherein a vertical thickness of the semiconductor die is greater than a combined vertical thickness of the riser structure and the component mounted to the riser structure.

15. The apparatus of claim 10, wherein the semiconductor die is mounted to the first surface of the substrate.

16. The apparatus of claim 15, wherein a minimum horizontal spacing between the semiconductor die and the riser structure is 250 microns.

17. The apparatus of claim 10, further comprising a plurality of contact structures disposed on the second surface of the substrate.

18. The apparatus of claim 1, wherein the apparatus is incorporated into another apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

19. An apparatus, comprising:
a substrate comprising a first surface and a second surface opposite the first surface, the substrate further comprising a first metal layer disposed on the first surface of the substrate, the first metal layer comprising a first plurality of electrical traces, and a second metal layer disposed on the second surface of the substrate, the second metal layer comprising a second plurality of electrical traces;
a first riser structure disposed above a portion of the first surface of the substrate, the portion occupying an area that is less than a total area of the first surface of the substrate, the portion including at least some of the first plurality of electrical traces, the first riser structure comprising a first insulating structure having a third surface in contact with the first surface of the substrate and a fourth surface opposite the third surface, and a third metal layer disposed on the fourth surface of the first insulating structure, the third metal layer comprising a third plurality of electrical traces for electrically coupling the substrate to a component to be mounted to the first riser structure; and
a second riser structure disposed above a portion of the second surface of the substrate, the portion occupying an area that is less than a total area of the second surface of the substrate, the portion including at least some of the second plurality of electrical traces, the second riser structure comprising a second insulating structure having a fifth surface in contact with the second surface of the substrate and a sixth surface opposite the fifth surface, and a fourth metal layer disposed on the sixth surface of the second insulating structure, the fourth metal layer comprising a fourth plurality of electrical traces for electrically coupling the substrate to a component to be mounted to the second riser structure.

20. A method of fabricating an apparatus, the method comprising:
providing a substrate comprising a first surface and a second surface opposite the first surface, the substrate further comprising a first metal layer disposed on the first surface of the substrate, the first metal layer comprising a first plurality of electrical traces for electrically coupling to a semiconductor die to be mounted to the substrate; and
forming a riser structure disposed above a portion of the first surface of the substrate, the portion occupying an area that is less than a total area of the first surface of the substrate, the portion including at least some of the first plurality of electrical traces, wherein forming the riser structure comprises forming a first insulating structure having a third surface in contact with the first surface of the substrate and a fourth surface opposite the third surface; and forming a second metal layer disposed on the fourth surface of the first insulating structure, the second metal layer comprising a second plurality of electrical traces for electrically coupling to a component to be mounted to the riser structure.
